(19) United States
(12) Patent Application Publication
(10) Pub. No.: US 2024/0224742 A1
(43) Pub. Date: Jul. 4, 2024

(54) DISPLAY APPARATUS

(71) Applicant: LG Display Co., Ltd., Seoul (KR)

(72) Inventors: SeoHyun NAM, Paju-si (KR); SeHong PARK, Paju-si (KR); Wonrae KIM, Paju-si (KR); Inae CHOI, Paju-si (KR); Sejong SEONG, Paju-si (KR)

(21) Appl. No.: 18/474,766

(22) Filed: Sep. 26, 2023

(30) Foreign Application Priority Data
Dec. 29, 2022 (KR) 10-2022-0188381

(51) Int. Cl. H10K 59/80; H10K 59/122

(52) U.S. Cl. CPC H10K 59/878; H10K 59/122

(57) ABSTRACT

A display apparatus is provided, which may improve light extraction efficiency of light emitted from a light emitting element layer. The display apparatus comprises a substrate having a plurality of pixels having a plurality of subpixels, a pattern portion disposed on the substrate and formed to be concave between the plurality of subpixels, and a reflective portion on the pattern portion, wherein the plurality of subpixels include a light emission area and a non-light emission area adjacent to the light emission area, and a light extraction portion that overlaps the light emission area and includes a plurality of concave portions, and the reflective portion is adjacent to the light extraction portion in the non-light emission area and is disposed to be spaced apart from the light emission area.

### CROSS-REFERENCE TO RELATED APPLICATION

This application claims the benefit of the Korean Patent Application No. 10-2022-0188381 filed on Dec. 29, 2022, which is hereby incorporated by reference as if fully set forth herein.

### BACKGROUND

### Technical Field

The present disclosure relates to a display apparatus for displaying an image.

### Description of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

Such a display apparatus displays an image through light emission of a light emitting element layer that includes a light emitting layer interposed between two electrodes.

### BRIEF SUMMARY

The inventors have realized that light extraction efficiency of the display apparatus is reduced as some of light emitted from the light emitting element layer is not emitted to the outside due to total reflection on the interface between the light emitting element layer and an electrode and/or between a substrate and an air layer. Various embodiments of the present disclosure has been made in view of the technical problems in the related art including the above identified problems. Various embodiments of the present disclosure provide a display apparatus that may improve light extraction efficiency of light emitted from a light emitting element layer.

Various embodiments of the present disclosure to provide a display apparatus that may further improve light extraction efficiency through light extraction from a non-light emission area.

Various embodiments of the present disclosure provide a display apparatus that may reduce overall power consumption through light extraction from a non-light emission area.

Various embodiments of the present disclosure as mentioned above, additional technical benefits and features of the present disclosure will be clearly understood by those skilled in the art from the following description of the present disclosure.

In accordance with an aspect of the present disclosure, the above and other objects can be accomplished by the provision of a display apparatus comprising a substrate having a plurality of pixels having a plurality of subpixels, a pattern portion disposed on the substrate and formed to be concave between the plurality of subpixels, and a reflective portion on the pattern portion, wherein the plurality of subpixels include a light emission area and a non-light emission area adjacent to the light emission area, and a light extraction portion that overlaps the light emission area and includes a plurality of concave portions, and the reflective portion is adjacent to the light extraction portion in the non-light emission area and is disposed to be spaced apart from the light emission area.

In accordance with another aspect of the present disclosure, the above and other objects can be accomplished by the provision of a display apparatus comprising a substrate having a plurality of pixels having a plurality of subpixels, a pattern portion disposed on the substrate and formed to be concave between the plurality of subpixels, and a reflective portion on the pattern portion, wherein the plurality of subpixels include a light emission area and a non-light emission area adjacent to the light emission area, and a depth of the reflective portion disposed in the non-light emission area is greater than a horizontal distance from an end of the light emission area to the reflective portion.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a schematic plan view illustrating a display apparatus according to one embodiment of the present disclosure;

FIG. 2 is a schematic cross-sectional view taken along line I-I′ shown in FIG. 2;

FIG. 3 is an enlarged view illustrating a portion A of FIG. 2;

FIGS. 4A and 4B are various examples schematically illustrating a portion of a display apparatus according to one embodiment of the present disclosure;

FIG. 4C illustrates a comparative example; and

FIG. 5 is a schematic graph illustrating light efficiency based on a distance between a light emission area and a reflective portion of FIGS. 4A to 4C.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a dimension (e.g., length, width, height, thickness, radius, diameter, area, etc.), a ratio, an angle, and a number of elements disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description. In describing a position relationship, for example, when a position relation between two parts is described as ‘on˜,’ ‘over˜,’ ‘under˜,’ and ‘next˜,’ one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction.” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

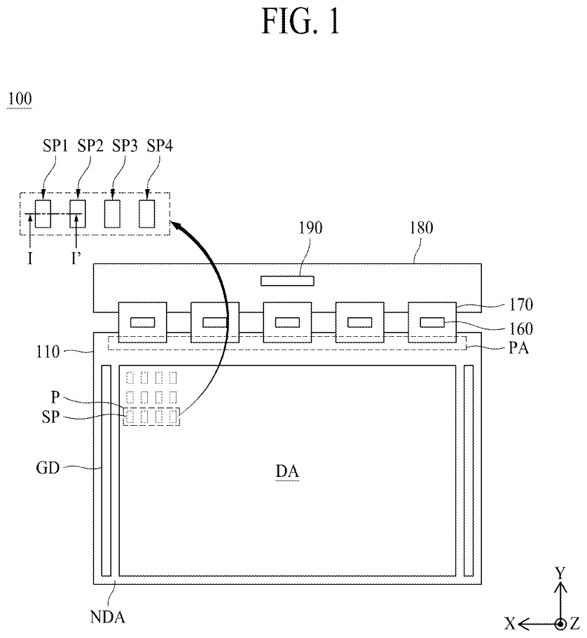

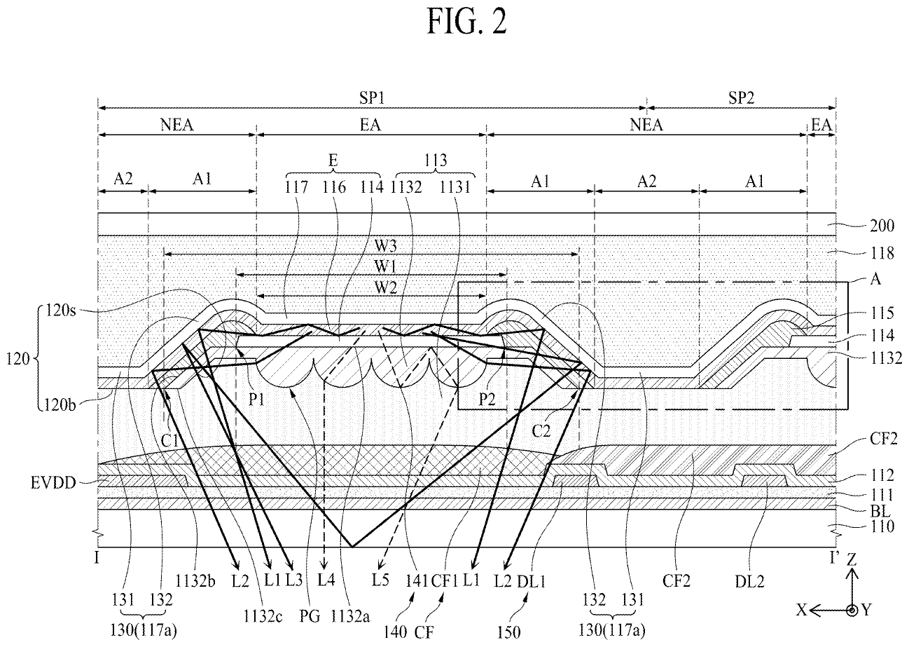

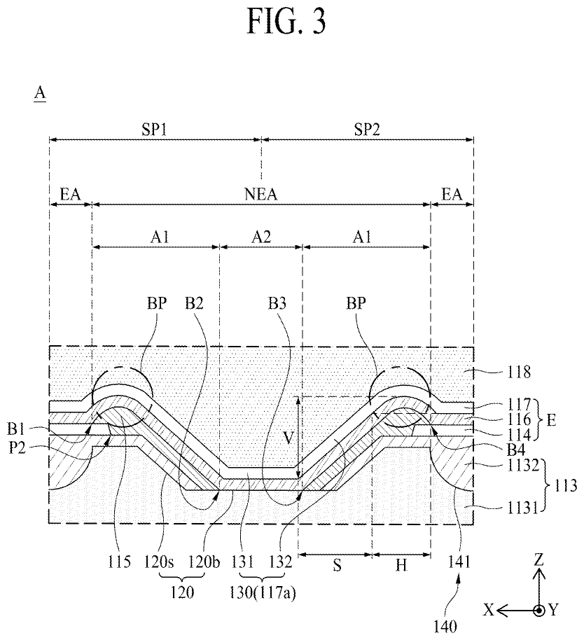

FIG. 1 is a schematic plan view illustrating a display apparatus according to one embodiment of the present disclosure, FIG. 2 is a schematic cross-sectional view taken along line I-I′ shown in FIG. 2, and FIG. 3 is an enlarged view illustrating a portion A of FIG. 2.

Referring to FIGS. 1 to 3, a display apparatus 100 according to one embodiment of the present disclosure includes a substrate 110 having a plurality of pixels P having a plurality of subpixels SP, a pattern portion 120 (also referred to as a pattern structure 120 or a pattern member 120) disposed on the substrate 110 and formed to be concave between the plurality of subpixels SP, and a reflective portion 130 (also referred to as a reflective structure 130 or a reflective member 130) on the pattern portion 120.

The plurality of subpixels SP may include a light emission area EA, a non-light emission area NEA adjacent to the light emission area EA and a light extraction portion 140 (also referred to as a light extraction structure 140 or a light extraction member 140) that overlaps the light emission area EA and includes a plurality of concave portions 141. As shown in FIG. 2, since the plurality of concave portions 141 may be provided in the form of a parabola, the plurality of concave portions 141 may be expressed as terms such as a parabolic or parabolic structure. The light emission area EA is an area from which light is emitted, and may be included in the display area DA. The non-light emission area NEA is an area from which light is not emitted, and may be an area adjacent to the light emission area EA. The non-light emission area NEA may be referred to as a term of a peripheral area. The reflective portion 130 may be adjacent to the light extraction portion 140 in the non-light emission area NEA, and may be spaced apart from the light emission area EA.

Therefore, in the display apparatus 100 according to one embodiment of the present disclosure, since the reflective portion 130 disposed in the non-light emission area NEA may reflect light, which is directed toward the subpixel adjacent thereto among light emitted from the light emission area EA, toward the subpixel SP for emitting light, light efficiency (or light extraction efficiency) of the subpixel SP for emitting light may be improved.

Meanwhile, when the reflective portion 130 is disposed to be too close to the light emission area EA, light reflectance by a wave guide is improved, but the light is trapped by the concave portion 141 of the light extraction portion 140, whereby light extraction efficiency may be deteriorated. On the contrary, when the reflective portion 130 is disposed to be far away from the light emission area EA, the amount of light reaching the reflective portion 130 is reduced, whereby light extraction efficiency may be deteriorated. Therefore, in the display apparatus 100 according to one embodiment of the present disclosure, the distance between the light emission area EA and the reflective portion 130 disposed to be inclined with respect to the non-light emission area NEA may be optimized to increase the amount of the light reaching the reflective portion 130 while minimizing the light trapped in the concave portion 141, whereby overall light efficiency (or light extraction efficiency) may be improved. An optimal distance between the light emission area EA and the reflective portion 130 may be derived by an equation related to an aspect ratio constant of the concave portion, an effective refractive index of the light emitting layer, a width and depth of the reflective portion 130. This will be described later.

The non-light emission area NEA according to one example may include a first area A1 adjacent to the light emission area EA and a second area A2 adjacent to the first area A1 and spaced apart from the light emission area EA. The first area A1 according to one example may be a bank area in which a bank (or a bank covering an edge of the pixel electrode) defining the light emission area EA is disposed. The second area A2 according to one example may be a bank-less area in which a bank is not disposed.

The pattern portion 120 according to one example may be formed to be concave the non-light emission area NEA. For example, the pattern portion 120 may be formed to be concave in an overcoat layer 113 (shown in FIG. 2) on the substrate 110. The pattern portion 120 may be disposed to be spaced apart from the light emission area EA. The pattern portion 120 according to one example may be provided to surround the light emission area EA in the form of a slit or a trench. For example, a width of the pattern portion 120 may be formed to be reduced from the reflective portion 130 toward the substrate 110. Also, as shown in FIG. 2, the pattern portion 120 may include an area exposed without being covered by the bank 115. Therefore, the pattern portion 120 may be expressed as terms such as a groove, a slit, a trench, a bank slit and a bank trench. As shown in FIG. 2, the pattern portion 120 may include an inclined surface 120s formed in the first area A1 and a bottom surface 120b extending from the inclined surface 120s to the second area A2.

The reflective portion 130 according to one example may be formed to be concave along a profile of the pattern portion 120 formed to be concave the non-light emission area NEA, thereby being formed to be concave the non-light emission area NEA. The reflective portion 130 may be made of a material capable of reflecting light, and may reflect light, which is emitted from the light emission area EA and directed toward the adjacent subpixel SP, toward the light emission area EA for emitting light. As shown in FIG. 2, since the reflective portion 130 is disposed to be inclined on the pattern portion 120 while surrounding the light emission area EA, the reflective portion 130 may be expressed as terms such as a side reflective portion or an inclined reflective portion.

Meanwhile, the display apparatus 100 according to one embodiment of the present disclosure may be implemented in a bottom emission type in which light emitted from the light emission area EA is emitted to the lower surface of the substrate 110. Therefore, in the display apparatus 100 according to one embodiment of the present disclosure, the light emitted to the lower surface of the substrate 110 may be the light in which direct light emitted from the light emission area EA and directly emitted to the lower surface of the substrate 110 and reflective light obtained by reflecting the light, which is emitted from the light emission area EA and directed toward the adjacent subpixel SP, by the reflective portion 130 and emitting the light to the lower surface of the substrate 110 are combined with each other. Therefore, the display apparatus 100 according to one embodiment of the present disclosure may more improve light extraction efficiency than the display apparatus in which the reflective portion 130 formed to be concave is not provided.

Hereinafter, reference to FIGS. 1 to 3, the display apparatus 100 according to an embodiment of the present specification will be described in more detail.

Referring to FIGS. 1 and 2, the display apparatus 100 according to one embodiment of the present disclosure may include a display panel having a gate driver GD, a light extraction portion 140 overlapping a light emission area EA, a plurality of lines 150, a source drive integrated circuit (hereinafter, referred to as “IC”) 160, a flexible film 170, a circuit board 180, and a timing controller 190.

The display panel may include a substrate 110 and an opposite substrate 200 (shown in FIG. 2).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA.

The display area DA is an area where an image is displayed, and may be a pixel array area, an active area, a pixel array unit, a display unit, or a screen. For example, the display area DA may be disposed at a central portion of the display panel. The display area DA may include a plurality of pixels P.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate.

The gate driver GD supplies gate signals to the gate lines in accordance with the gate control signal input from the timing controller 190. The gate driver GD may be formed on one side of the light emission area EA or in the non-light emission area NEA outside both sides of the light emission area EA in a gate driver in panel (GIP) method, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for outputting an image to the pixel P provided in the display area DA. Referring to FIG. 1, the pad area PA may be provided above the display area DA.

The source drive IC 160 receives digital video data and a source control signal from the timing controller 190. The source drive IC 160 converts the digital video data into analog data voltages in accordance with the source control signal and supplies the analog data voltages to the data lines. When the source drive IC 160 is manufactured as a driving chip, the source drive IC 160 may be packaged in the flexible film 170 in a chip on film (COF) method or a chip on plastic (COP) method.

Pads, such as data pads, may be formed in the non-display area NDA of the display panel. Lines connecting the pads with the source drive IC 160 and lines connecting the pads with lines of the circuit board 180 may be formed in the flexible film 170. The flexible film 170 may be attached onto the pads by using an anisotropic conducting film, whereby the pads may be connected with the lines of the flexible film 170.

The circuit board 180 may be attached to the flexible films 170. A plurality of circuits implemented as driving chips may be packaged in the circuit board 180. For example, the timing controller 190 may be packaged in the circuit board 180. The circuit board 180 may be a printed circuit board or a flexible printed circuit board.

The timing controller 190 receives the digital video data and a timing signal from an external system board through a cable of the circuit board 180. The timing controller 190 generates a gate control signal for controlling an operation timing of the gate driver GD and a source control signal for controlling the source drive ICs 160 based on the timing signal. The timing controller 190 supplies the gate control signal to the gate driver GD, and supplies the source control signal to the source drive ICs 160.

Referring to FIG. 2, the substrate 110 according to an example may include the light emission area EA and the non-light emission area NEA.

The light emission area EA is an area from which light is emitted, and may mean an area that is not covered by a bank 115. A light emitting element E, which includes a pixel electrode 114, a light emitting layer 116 and a reflective electrode 117, may be disposed in the light emission area EA. When an electric field is formed between the pixel electrode 114 and the reflective electrode 117, the light emitting layer 116 in the light emission area EA may emit light.

The light emission area EA according to an example may include gate lines, data lines, pixel driving power lines, and a plurality of pixels P. Each of the plurality of pixels P may include a plurality of subpixels SP that may be at the location where the gate lines and the data lines overlap.

Meanwhile, at least four subpixels, which are provided to emit different colors and disposed to be adjacent to one another, among the plurality of subpixels SP may constitute one pixel P (or unit pixel). One pixel P may include, but is not limited to, a red subpixel, a green subpixel, a blue subpixel and a white subpixel. One pixel P may include three subpixels SP provided to emit light of different colors and disposed to be adjacent to one another. For example, one pixel P may include a red subpixel, a green subpixel and a blue subpixel.

Each of the plurality of subpixels SP includes a thin film transistor and a light emitting element E connected to the thin film transistor. Each of the plurality of subpixels may include a light emitting layer (or an organic light emitting layer) 116 (shown in FIG. 2) interposed between the pixel electrode and the reflective electrode. The light emitting layer 116 may be disposed in the light emission area EA and the non-light emission area NEA under the reflective portion 130.

The light emitting layer respectively disposed in the plurality of subpixels SP may individually emit light of different colors or emit white light in common. Since the light emitting layer of each of the plurality of subpixels SP commonly emit white light, each of the red subpixel, the green subpixel and the blue subpixel may include a color filter CF (or wavelength conversion member CF) for converting white light into light of its respective different color. In this case, the white subpixel may not include a color filter.

In the display apparatus 100 according to one embodiment of the present disclosure, an area provided with a red color filter may be a red subpixel or a first subpixel, an area provided with a green color filter may be a green subpixel or a second subpixel, an area provided with a blue color filter may be a blue subpixel or a third subpixel, and an area in which the color filter is not provided may be a white subpixel or a fourth subpixel.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The plurality of subpixels SP according to one example may be disposed to be adjacent to each other in a first direction (X-axis direction). The first direction (X-axis direction) may be a horizontal direction based on FIG. 1. The horizontal direction may be a direction in which a gate line is disposed.

A second direction (Y-axis direction) is a direction crossing the first direction (X-axis direction), and may be a vertical direction based on FIG. 1. The vertical direction may be a direction in which a data line is disposed.

A third direction (Z-axis direction) is a direction crossing each of the first direction (X-axis direction) and the second direction (Y-axis direction), and may be a thickness direction of the display apparatus 100.

The plurality of subpixels SP may include a first subpixel SP1, a second subpixel SP2, a third subpixel SP3 and a fourth subpixel SP4 arranged adjacent to each other in the first direction (X-axis direction). For example, the first subpixel SP1 may be a red subpixel, the second subpixel SP2 may be a green subpixel, the third subpixel SP3 may be a blue subpixel and the fourth subpixel SP4 may be a white subpixel, but is not limited thereto. However, the arrangement order of the first subpixel SP1, the second subpixel SP2, the third subpixel SP3 and the fourth subpixel SP4 may be changed.

Each of the first to fourth subpixels SP1 to SP4 may include a light emission area EA and a circuit area. The light emission area EA may be disposed at one side (or an upper side) of a subpixel area, and the circuit area may be disposed at the other side (or a lower side) of the subpixel area. For example, the circuit area may be disposed at the lower side of the light emission area EA based on the second direction (Y-axis direction). The light emission areas EA of the first to fourth subpixels SP1 to SP4 may have different sizes (or areas).

The first to fourth subpixels SP1 to SP4 may be disposed to be adjacent to one another along the first direction (X-axis direction). For example, two data lines extended along the second direction (Y-axis direction) may be disposed in parallel with each other between the first subpixel SP1 and the second subpixel SP2 and between the third subpixel SP3 and the fourth subpixel SP4. A pixel power line extended along the first direction (X-axis direction) may be disposed between the light emission area EA and the circuit area of each of the first to fourth subpixels SP1 to SP4. The gate line and a sensing line may be disposed below the circuit area. The pixel power line EVDD (shown in FIG. 2) extended along the second direction (Y-axis direction) may be disposed at one side of the first subpixel SP1 or the fourth subpixel SP4. A reference line extended along the second direction (Y-axis direction) may be disposed between the second subpixel SP2 and the third subpixel SP3. The reference line may be used as a sensing line for sensing a change of characteristics of a driving thin film transistor and/or a change of characteristics of the light emitting element layer, which is disposed in the circuit area, from the outside in a sensing driving mode of the pixel P.

The data lines, the pixel power line EVDD and the reference line may be included in the plurality of lines 150. The data lines may include a first data line DL1 for driving the first subpixel SP1, a second data line DL2 for driving the second subpixel SP2, a third data line for driving the third subpixel SP3 and a fourth data line for driving the fourth subpixel SP4.

The plurality of lines 150 may be provided below the pattern portion 120. Each of the plurality of lines 150 may at least partially overlap the pattern portion 120 below the pattern portion 120. For example, as shown in FIG. 2, the first data line DL1 may overlap a bottom surface 120b of the pattern portion 120. The second data line DL2 may partially overlap the bottom surface 120b and an inclined surface 120s of the pattern portion 120. The pixel power line EVDD or the reference line may partially overlap the bottom surface 120b and the inclined surface 120s of the pattern portion 120.

In the display apparatus 100 according to one embodiment of the present disclosure, each of the plurality of subpixels SP may include the light extraction portion 140. The light extraction portion 140 may be formed on the overcoat layer 113 (shown in FIG. 2) to overlap the light emission area EA of the subpixel. The light extraction portion 140 may be formed on the overcoat layer 113 of the light emission area EA to have a curved (or uneven) shape, thereby changing a propagation path of light emitted from the light emitting element E to increase light extraction efficiency. For example, the light extraction portion 140 may be a non-flat portion, an uneven pattern portion, a micro lens portion, or a light scattering pattern portion.

The light extraction portion 140 may include a plurality of grooves 141 (or a plurality of grooves PG). In one embodiment, each groove of the plurality has a U-shaped groove. Due to the U-shaped groove, the plurality of grooves 141 may also be referred to as a plurality of concave portions 141. Accordingly, the light extraction portion 140 may include a plurality of concave portions 141. The plurality of concave portions 141 may be formed to be concave inside the overcoat layer 113. For example, the plurality of concave portions 141 may be formed or configured to be concave from an upper surface 1131a of a first layer 1131 included in the overcoat layer 113. Therefore, the first layer 1131 may include a plurality of concave portions 141. The first layer 1131 may be disposed between the substrate 110 and the light emitting element E. The first layer 1131 of the overcoat layer 113 may also be referred to as a first overcoat layer 1131.

A second layer 1132 of the overcoat layer 113 may be disposed between the first layer 1131 and a light emitting element E (or a pixel electrode 114 shown in FIG. 2). The second layer 1132 of the overcoat layer 113 may also be referred to as a second overcoat layer 1132. The second layer 1132 according to one example may be formed to be wider than the pixel electrode 114 in a first direction (X-axis direction). Thus, a portion of the second layer 1132 may overlap the light emissive area EA, and the other portion of the second layer 1132 may be in contact with a portion of the bottom surface 120b while covering the inclined surface 120s of the pattern portion 120. That is, as shown in FIG. 2, the second layer 1132 may be extended from the light emission area EA to the first area A1 and thus may be in contact with a portion of the bottom surface 120b while covering the inclined surface 120s of the pattern portion 120. Since an upper surface 1132a of the second layer 1132 is provided flat, the pixel electrode 114 disposed on the upper surface 1132a of the second layer 1132 may also be provided flat. The light emitting layer 116 may be disposed on the second layer 1132.

Meanwhile, a refractive index of the second layer 1132 may be greater than that of the first layer 1131. Therefore, as shown in FIG. 2, a path of light emitted from a light emitting layer 116 and directed toward the substrate 110 may be changed toward the reflective portion 130 due to a difference in refractive indexes between the second layer 1132 and the first layer 1131 of the light extraction portion 140. Therefore, the light having a path formed in the reflective portion 130 by the light extraction portion 140 may be reflected in the reflective portion 130 and emitted toward the light emission area EA of the subpixel SP for emitting light. Hereinafter, the light reflected in the reflective portion 130 and emitted toward the substrate 110 will be defined as the reflective light.

As shown in FIG. 2, the reflective light may include first reflective light L1 (or WG mode extraction light L1) reflected from the reflective portion 130 and emitted to the substrate 110 after being subjected to optical waveguide through total reflection between the pixel electrode 114 and the reflective electrode 117, second reflective light L2 reflected from the reflective portion 130 and emitted to the substrate 110 after its path is changed by the light extraction portion 140, and third reflective light L3 (or substrate mode extraction light) emitted from the light emitting layer 116, primarily reflected by the reflective portion 130, secondarily reflected on a boundary surface between the lower surface of the substrate 110 and the air layer, thirdly reflected by the reflective portion 130 and then emitted to the substrate 110. The first reflective light L1, the second reflective light L2 and the third reflective light L3, which are shown in solid lines in FIG. 3, may be the reflective light extracted by being reflected by the reflective portion 130.

As shown in FIG. 2, the first reflective light L1 according to one example may be emitted from the light emission area EA. The second reflective light L2 may be emitted from a position spaced apart from the light emission area EA. That is, the second reflective light L2 may be emitted from the non-light emission area NEA or the peripheral area. However, the present disclosure is not limited to the above example. The first reflective light L1 may be emitted toward the substrate 110 from the position spaced apart from the light emission area EA. The third reflective light L3 may be emitted from the light emission area EA or the non-light emission area NEA.

The display apparatus 100 according to one embodiment of the present disclosure may further include light which is emitted to the substrate 110 through the light extraction portion 140 without being reflected by the reflective portion 130. For example, as shown by the dotted line in FIG. 2, the display apparatus 100 may further include primary extraction light LA emitted from the light emitting layer 116, refracted on a boundary surface between the plurality of concave portions 141 included in the light extraction portion 140 and the first layer 1131 and then emitted to the substrate 110, and recycle light L5 emitted from the light emitting layer 116, primarily refracted on the boundary surface between the plurality of concave portions 141 and the first layer 1131, secondarily reflected on the lower surface of the pixel electrode 114, refracted on the boundary surface between the plurality of concave portions 141 and the first layer 1131 and then emitted to the substrate 110. Therefore, the display apparatus 100 according to one embodiment of the present disclosure may improve the overall light extraction efficiency through the light extraction portion 140 and the reflective portion 130.

In the display apparatus 100 according to one embodiment of the present disclosure, since the pattern portion 120 is disposed to surround the light emission area EA, at least a portion of the reflective portion 130 on the pattern portion 120 may be disposed to surround the light emission area EA. Therefore, the reflective light may be emitted toward the substrate 110 from the position spaced apart from the light emission area EA while surrounding at least a portion of the light emission area EA. Therefore, in the display apparatus 100 according to one embodiment of the present disclosure, since light dissipated by waveguide (or optical waveguide) and/or light dissipated by the interface total reflection may be emitted from the non-light emission area NEA in the form of reflective light through the reflective portion 130 surrounding at least a portion of the light emission area EA, light extraction efficiency may be improved and the overall light emission efficiency may be increased.

Hereinafter, a structure of each of the plurality of subpixels SP will be described in detail.

Referring to FIG. 2, the display apparatus 100 according to one embodiment of the present disclosure may further include a buffer layer BL, a circuit element layer, a thin film transistor (not shown), a pixel electrode 114, a bank 115, a light emitting layer 116, a reflective electrode 117, an encapsulation layer 118 and a color filter CF.

In more detail, each of the subpixels SP according to one embodiment may include a circuit element layer provided on an upper surface of a buffer layer BL, including a gate insulating layer (not shown), an interlayer insulating layer 111 and a passivation layer 112, an overcoat layer 113 provided on the circuit element layer, a pixel electrode 114 provided on the overcoat layer 113, a bank 115 covering an edge of the pixel electrode 114, a light emitting layer 116 on the pixel electrode 114 and the bank 115, a reflective electrode 117 on the light emitting layer 116, and an encapsulation layer 118 on the reflective electrode 117.

The thin film transistor for driving the subpixel SP may be disposed on the circuit element layer. The circuit element layer may be expressed in terms of an inorganic film layer. The pixel electrode 114, the light emitting layer 116 and the reflective electrode 117 may be included in the light emitting element E.

The buffer layer BL may be formed between the substrate 110 and the gate insulating layer to protect the thin film transistor. The buffer layer BL may be disposed on the entire surface (or front surface) of the substrate 110. The pixel power line EVDD for pixel driving may be disposed between the buffer layer BL and the substrate 110. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor (or a drive transistor) according to an example may include an active layer, a gate electrode, a source electrode, and a drain electrode. The active layer may include a channel area, a drain area and a source area, which are formed in a thin film transistor area of a circuit area of the subpixel SP. The drain area and the source area may be spaced parallel to each other with the channel area interposed therebetween.

The active layer may be formed of a semiconductor material based on any one of amorphous silicon, polycrystalline silicon, oxide and organic material.

The gate insulating layer may be formed on the channel area of the active layer. As an example, the gate insulating layer may be formed in an island shape only on the channel area of the active layer, or may be formed on an entire front surface of the substrate 110 or the buffer layer BL, which includes the active layer.

The gate electrode may be formed on the gate insulating layer to overlap the channel area of the active layer.

The interlayer insulating layer 111 may be formed to partially overlap the gate electrode and the drain area and source area of the active layer. The interlayer insulating layer 111 may be formed over the entire light emission area where light is emitted in the circuit area and the subpixel SP.

The source electrode may be electrically connected to the source area of the active layer through a source contact hole provided in the interlayer insulating layer overlapped with the source area of the active layer. The drain electrode may be electrically connected to the drain area of the active layer through a drain contact hole provided in the interlayer insulating layer 111 overlapped with the drain area of the active layer.

The drain electrode and the source electrode may be made of the same metal material. For example, each of the drain electrode and the source electrode may be made of a single metal layer, a single layer of an alloy or a multi-layer of two or more layers, which is the same as or different from that of the gate electrode.

In addition, the circuit area may further include first and second switching thin film transistors disposed together with the thin film transistor, and a capacitor. Since each of the first and second switching thin film transistors is provided on the circuit area of the subpixel SP to have the same structure as that of the thin film transistor, its description will be omitted. The capacitor (not shown) may be provided in an overlap area between the gate electrode and the source electrode of the thin film transistor, which overlap each other with the interlayer insulating layer 111 interposed therebetween.

Additionally, in order to prevent a threshold voltage of the thin film transistor provided in a pixel area from being shifted by light, the display panel or the substrate 110 may further include a light shielding layer (not shown) provided below the active layer of at least one of the thin film transistor, the first switching thin film transistor or the second switching thin film transistor. The light shielding layer may be disposed between the substrate 110 and the active layer to shield light incident on the active layer through the substrate 110, thereby minimizing a change in the threshold voltage of the transistor due to external light. Also, since the light shielding layer is provided between the substrate 110 and the active layer, the thin film transistor may be prevented from being seen by a user.

The passivation layer 112 may be provided on the substrate 110 to cover the pixel area. The passivation layer 112 covers a drain electrode, a source electrode and a gate electrode of the thin film transistor, and the buffer layer. The reference line may be disposed between the passivation layer 112 and the interlayer insulating layer 111. The reference line may be disposed at a position symmetrical to the pixel power line EVDD based on the light emission area EA or a similar position symmetrical to the pixel power line EVDD. Therefore, the reference line and the pixel power line EVDD may be disposed below the bank 115 without covering the light emitting area EA. The passivation layer 112 may be formed over the circuit area and the light emission area. The passivation layer 112 may be omitted. The color filter CF may be disposed on the passivation layer 112.

The overcoat layer 113 may be provided on the substrate 110 to cover the passivation layer 112 and the color filter CF. When the passivation layer 112 is omitted, the overcoat layer 113 may be provided on the substrate 110 to cover the circuit area. The overcoat layer 113 may be formed in the circuit area in which the thin film transistor is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

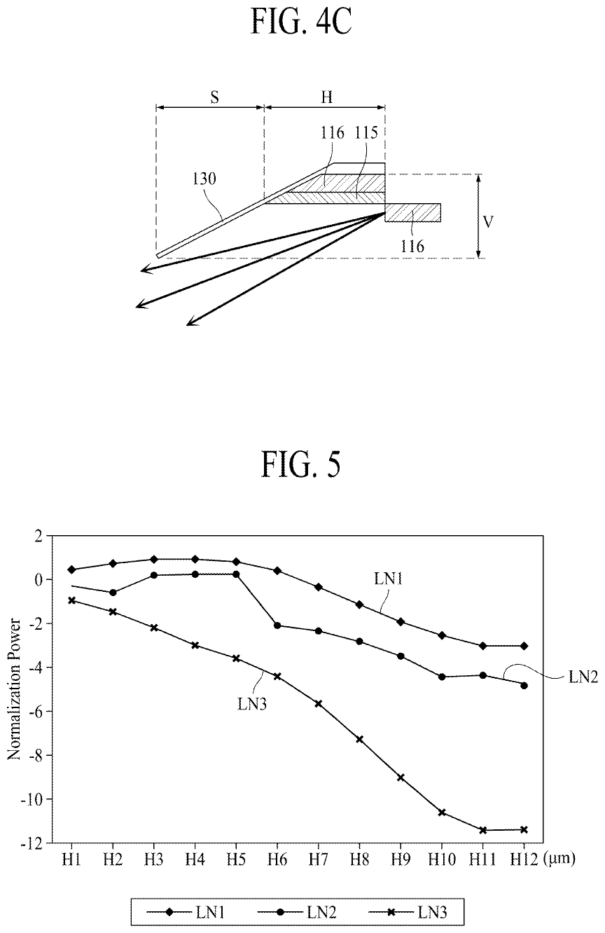

The overcoat layer 113 formed in the display area DA (or the light emission area EA) may include a plurality of concave portions 141. The plurality of concave portions 141 are the elements of the light extraction portion 140 for increasing light efficiency of the light emission area EA, and may be formed inside the overcoat layer 113. In detail, as shown in FIG. 5, the plurality of concave portions 141 may be formed in a concave shape on the first layer 1131 of the overcoat layer 113. The plurality of concave portions 141 are provided to be connected to each other so that an embossed shape may be formed in the first layer 1131.

The second layer 1132 having a refractive index higher than that of the first layer 1131 may be formed on the first layer 1131. A path of the light, which is directed toward the adjacent subpixel SP, among the light emitted from the light emitting element E may be changed toward the reflective portion 130 in accordance with a difference in the refractive index between the second layer 1132 and the first layer 1131. The second layer 1132 may be provided to cover the embossed shape of the first layer 1131 and thus the upper surface 1132a may be provided to be flat.

The pixel electrode 114 is formed on the upper surface 1132a of the second layer 1132 so that the pixel electrode 114 may be provided to be flat, and the light emitting layer 116 and the reflective electrode 117, which are formed on the pixel electrode 114, may be provided to be also flat. Since the pixel electrode 114, the light emitting layer 116, the reflective electrode 117, that is, the light emitting element E is provided to be flat in the light emission area EA, a thickness of each of the pixel electrode 114, the light emitting layer 116 and the reflective electrode 117 in the light emission area EA may be uniformly formed. Therefore, the light emitting layer 116 may be uniformly emitted without deviation in the light emission area EA.

The plurality of concave portions 141 may be formed on the first layer 1131 through a photo process using a mask having an opening portion and then a pattern (or etching) or ashing process after the first layer 1131 is coated to cover the passivation layer 111c and the color filter CF. The plurality of concave portions 141 may be formed in an area overlapped with the color filter CF and/or an area that is not overlapped with the bank 115 of the non-light emission area NEA, but are not limited thereto. A portion of the plurality of concave portions 141 may be formed to overlap the bank 115.

Referring back to FIG. 2, the color filter CF disposed in the light emission area EA may be provided between the substrate 110 and the overcoat layer 113. Therefore, the color filter CF may be disposed between the pixel power line EVDD, for example, the pixel power line EVDD and the reflective portion 130 or between the pixel driving line and the pattern portion 120. The color filter CF may include a red color filter (or a first color filter) CF1 for converting white light emitted from the light emitting layer 116 into red light, a green color filter (or a second color filter) CF2 for converting white light into green light, and a blue color filter (or a third color filter) CF3 for converting white light into blue light. The fourth subpixel, which is a white subpixel, may not include a color filter since the light emitting layer 116 emits white light.

As shown in FIG. 2, the display apparatus 100 according to one embodiment of the present disclosure may be provided such that color filters having different colors partially overlap each other at a boundary portion of the plurality of subpixels SP. In this case, the display apparatus 100 according to one embodiment of the present disclosure may prevent the light emitted from each subpixel SP from being emitted to the adjacent subpixel SP due to the color filters overlapped with each other at the boundary portion of the subpixels SP, thereby preventing color mixture between the subpixels SP from occurring.

The pixel electrode 114 of the subpixel SP may be formed on the overcoat layer 113. The pixel electrode 114 may be connected to a drain electrode or a source electrode of the thin film transistor through a contact hole passing through the overcoat layer 113 and the passivation layer 112. The edge portion of the pixel electrode 114 may be covered by the bank 115.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 is an area from which light is not emitted, and may be provided to surround each of the light emitting portions (or the concave portions 141) of each of the plurality of subpixels SP. That is, the bank 115 may partition (or define) the concave portions 141 of each of the light emitting portion or the subpixels SP. The light emitting portion may mean a portion where the pixel electrode 114 and the reflective electrode 117 are in contact with each of the upper surface and the lower surface of the light emitting layer 116 with the light emitting layer 116 interposed therebetween.

The bank 115 may be formed to cover the edge of each pixel electrode 114 of each of the subpixels SP and expose a portion of each of the pixel electrodes 114. That is, the bank 115 may partially cover the pixel electrode 114. Therefore, the bank 115 may prevent the pixel electrode 114 and the reflective electrode 117 from being in contact with each other at the end of each pixel electrode 114. The exposed portion of the pixel electrode 114, which is not covered by the bank 115, may be included in the light emitting portion (or the light emission area EA). As shown in FIG. 2, the light emitting portion may be formed on the plurality of concave portions 141, and thus the light emitting portion (or the light emission area EA) may overlap the concave portions 141 in a thickness direction (or the third direction (Z-axis direction)) of the substrate 110.

After the bank 115 is formed, the light emitting layer 116 may be formed to cover the pixel electrode 114 and the bank 115. Therefore, the bank 115 may be provided between the pixel electrode 114 and the light emitting layer 116. The bank 115 may be expressed as the term of a pixel defining layer. The bank 115 according to one example may include an organic material and/or an inorganic material. As shown in FIG. 2, the bank 115 may be formed along the profile of the pattern portion 120 (or the second layer 1132).

Referring again to FIG. 2, the light emitting layer 116 may be formed on the pixel electrode 114 and the bank 115. The light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the light emitting layer 116 may emit light. The light emitting layer 116 may be formed of a plurality of subpixels SP and a common layer provided on the bank 115.

The light emitting layer 116 according to an embodiment may be provided to emit white light. The light emitting layer 116 may include a plurality of stacks which emit lights of different colors. For example, the light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the light emitting layer 116 is provided as a common layer, the first stack, the charge generating layer, and the second stack may be arranged all over the plurality of subpixels SP.

The reflective electrode 117 may be formed on the light emitting layer 116. The reflective electrode 117 according to one example may include a metal material. The reflective electrode 117 may reflect the light emitted from the light emitting layer 116 in the plurality of subpixels SP toward the lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the light emitting layer 116 toward the substrate 110, and thus the reflective electrode 117 may be made of a metal material having high reflectance. The reflective electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

Meanwhile, in the display apparatus 100 according to one embodiment of the present disclosure, the reflective portion 130 may be a portion of the reflective electrode 117. Therefore, the reflective portion 130 may reflect light, which is directed toward the adjacent subpixel SP, toward the light emission area EA of the subpixel SP for emitting light. Since the reflective portion 130 is a portion of the reflection electrode 117, as shown in FIG. 2, the reflective portion 130 may be denoted by a reference numeral 117a. In the present disclosure, the reflective portion 130 may mean the reflective electrode 117 that overlaps the pattern portion 120. In particular, the reflective portion 130 may mean the reflective electrode 117 that is inclined while being overlapped with the pattern portion 120. Therefore, as shown in FIG. 3, the reflective portion 130 may reflect light that is directed toward the adjacent subpixel SP, or light that is dissipated through total reflection between interfaces, toward the light emission area EA (or the non-light emission area NEA) of the subpixel SP for emitting light.

The encapsulation layer 118 is formed on the reflective electrode 117. The encapsulation layer 118 serves to prevent oxygen or moisture from being permeated into the light emitting layer 116 and the reflective electrode 117. To this end, the encapsulation layer 118 may include at least one inorganic film and at least one organic film.

Meanwhile, as shown in FIG. 2, the encapsulation layer 118 may be disposed not only in the light emission area EA but also in the non-light emission area NEA. The encapsulation layer 118 may be disposed between the reflective electrode 117 and an opposing substrate 200.

Hereinafter, the pattern portion 120 and the reflective portion 130 of the display apparatus 100 according to one embodiment of the present disclosure will be described in more detail with reference to FIGS. 2 and 3.

In the display apparatus 100 according to one embodiment of the present disclosure, the pattern portion 120 may be provided near the light emission area EA (or the non-light emission area NEA) and the reflective portion 130 may be provided on the pattern portion 120 in order to prevent light extraction efficiency from being reduced as some of the light emitted from the light emitting element layer is not discharged to the outside due to total reflection on an interface between the light emitting element layer and the electrode and/or an interface between the substrate and the air layer.

For example, as shown in FIG. 2, the pattern portion 120 may be formed to be concave in the first layer 1131 of the overcoat layer 113. As shown in FIG. 2, the pattern portion 120 may be disposed near the non-light emission area NEA. That is, the pattern portion 120 may be disposed to surround the light emission area EA while being adjacent to the light extraction portion 140. The pattern portion 120 may be formed in the non-light emission area NEA together with the plurality of concave portions 141 when the plurality of concave portions 141 are formed in the light emission area EA. The pattern portion 120 may include a bottom surface 120b and an inclined surface 120s.

The bottom surface 120b of the pattern portion 120 according to one embodiment is a surface formed to be closest to the substrate 110, or may be disposed to be closer to the substrate 110 (or the upper surface of the substrate) than the pixel electrode 114 (or the lower surface of the pixel electrode 114) in the light emission area EA. Therefore, as shown in FIG. 3, the bottom surface 120b of the pattern portion 120 may be provided to have a depth equal to or similar to that of each of the plurality of concave portions 141. However, when the depth of the pattern portion 120 is lower than that of the concave portion 141, since an area of the reflective portion 130 is reduced, light extraction efficiency may be reduced. Therefore, in the display apparatus 100 according to one embodiment of the present disclosure, the depth of the pattern portion 120 may be provided to be equal to or deeper than that of the concave portion 141.

The inclined surface 120s of the pattern portion 120 may be disposed between the bottom surface 120b and the light extraction portion 140. Therefore, the inclined surface 120s of the pattern portion 120 may be provided to surround the light emission area EA or the plurality of concave portions 141. As shown in FIG. 2, the inclined surface 120s may be connected to the bottom surface 120b. The inclined surface 120s may form a predetermined angle with the bottom surface 120b. For example, the angle formed by the inclined surface 120s and the bottom surface 120b may be an obtuse angle. Therefore, a width of the pattern portion 120 may be gradually reduced toward a direction (or the third direction (Z-axis direction)) from the opposing substrate 200 (or the reflective portion 130) toward the substrate 110. As the obtuse angle is formed by the inclined surface 120s and the bottom surface 120b, the light emitting element E (or the light emitting element E including the reflective portion 130) including the second layer 1132, the bank 115 and the reflective portion 130, which are formed in a subsequent process, may be formed to be concave along the profile of the pattern portion 120. Therefore, the light emitting element E may be formed to be concave on the pattern portion 120 formed to be concave in the non-light emission area NEA (or the peripheral area). The light emitting element E formed to be concave in the pattern portion 120 may mean that it includes at least one of the pixel electrode 114, the light emitting layer 116 or the reflective electrode 117.

As shown in FIG. 2, the pattern portion 120 may be provided to surround the light emission area EA. As the pattern portion 120 is provided to surround the light emission area EA, at least a portion of the reflective portion 130 disposed on the pattern portion 120 may be provided to surround the light emission area EA. Therefore, in the display apparatus 100 according to one embodiment of the present disclosure, since light may be extracted even from the non-light emission area NEA near the light emission area EA, overall light efficiency may be improved. Therefore, the display apparatus 100 according to one embodiment of the present disclosure may have the same light emission efficiency or more improved light emission efficiency even with low power as compared with a general display apparatus having no pattern portion 120 and reflective portion 130, whereby overall power consumption may be reduced.

In addition, the display apparatus 100 according to one embodiment of the present disclosure may allow the light emitting element E to emit light even with low power, thereby improving lifespan of the light emitting element E.

Since the pattern portion 120 is disposed to surround the light emission area EA, the pattern portion 120 may be disposed between subpixels SP for emitting light of different colors. Therefore, the reflective portion 130 between the subpixels SP for emitting light of different colors may prevent light of different colors from being emitted to another adjacent subpixels SP. As a result, the display apparatus 100 according to the present disclosure may prevent color mixture (or color distortion) from occurring between the subpixels SP for emitting light of different colors, thereby improving color purity.

The second layer 1132 of the overcoat layer 113 may be further extended from the light emission area EA to the non-light emission area NEA to partially cover the inclined surface 120s of the pattern portion 120. Therefore, as shown in FIG. 3, an end 1132c of the second layer 1132 may be in contact with the bottom surface 120b of the pattern portion 120. In this case, the end 1132c of the second layer 1132 may be in contact with only a portion of the bottom surface 120b. When the second layer 1132 entirely covers the bottom surface 120b, the depth of the reflective portion 130 formed on the pattern portion 120 may be relatively lowered, thereby reducing reflective efficiency. Therefore, in the display apparatus 100 according to one embodiment of the present disclosure, the second layer 1132 is provided to be in contact with only a portion of the bottom surface 120b without entirely covering the bottom surface 120b of the pattern portion 120 and thus the reflective portion 130 formed in a subsequent process may be formed to be close to the bottom surface 120b, whereby reflective efficiency may be improved.

The bank 115 may be extended to cover the inclined surface 1132b of the second layer 1132 covering the inclined surface 120s of the pattern portion 120 while covering the edge of the pixel electrode 114. Therefore, the bank 115 may be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency may be reduced. Therefore, as shown in FIG. 3, each of the second layer 1132 and the bank 115 on the bottom surface 120b of the pattern portion 120 may be discontinuously provided. That is, each of the second layer 1132 and the bank 115 may be disconnected on the bottom surface 120b of the pattern portion 120. As a result, in the display apparatus 100 according to one embodiment of the present disclosure, the bank 115 is provided to be in contact with only a portion of the bottom surface 120b without entirely covering the bottom surface 120b, so that the reflective portion 130 formed in a subsequent process may be formed to be close to the bottom surface 120b, whereby reflective efficiency may be improved.

Since the bank 115 is provided to be in contact with only a portion of the bottom surface 120b of the pattern portion 120, the bank 115 may be disconnected from the pattern portion 120 as shown in FIG. 2. As the bank 115 is disconnected from the pattern portion 120, the reflective portion 130 disposed on the second pattern line 122 may be disposed to be close to the bottom surface 120b of the pattern portion 120. Therefore, the reflective portion 130 may be formed as deep as possible in the pattern portion 120 as compared with the case that the bank is not disconnected from the pattern portion 120, and thus reflective efficiency may be improved. As shown in FIGS. 2 and 3, since the pattern portion 120 is disposed between the subpixels SP, the second layer 1132, the bank 115, the light emitting layer 116 and the reflective portion 130 may be provided to be symmetrical based on the center of the pattern portion 120.

In the display apparatus 100 according to one embodiment of the present disclosure, the plurality of lines 150 may be disposed so as not to cover the light emission area EA (or so as not to overlap the light emission area EA). When the plurality of lines 150 overlap or cover the light emission area EA, the light reflected by the reflective portion 130 may be blocked by the plurality of lines 150 and thus cannot be emitted toward the substrate 110. Therefore, in the display apparatus 100 according to one embodiment of the present disclosure, the plurality of lines 150 may be provided so as not to overlap the light emission area EA, whereby light extraction efficiency may be maximized. Also, in the display apparatus 100 according to one embodiment of the present disclosure, the plurality of lines 150 may be provided so as not to overlap the light emission area EA, whereby an aperture ratio may be enlarged as compared with the case that the plurality of lines overlap the light emission area, and thus luminance may be improved. Although the arrangement structure of the plurality of lines 150 in the first subpixel SP1 and the second subpixel SP2 has been described with reference to FIG. 2, the above-described structure may be equally applied to the third subpixel SP3 and the fourth subpixel SP4. However, a line having a wide width, which is disposed among the first to fourth subpixels may be the reference line.

Meanwhile, as the bank 115 is disconnected from the pattern portion 120, the light emitting layer 116 and the reflective portion 130 (or the reflective electrode 117) formed in a subsequent process may be formed along a profile of the bottom surface 120b of the pattern portion 120 and the bank 115.

The reflective portion 130 according to one example may be formed to be concave on the pattern portion 120 along the profile of the pattern portion 120 formed to be concave near the non-light emission area NEA, thereby being formed to be concave near the non-light emission area NEA. The reflective portion 130 may be made of a material capable of reflecting light to reflect light, which is emitted from the light emission area EA and directed toward the subpixel SP adjacent thereto, toward the light emission area EA of the subpixel SP for emitting light. As shown in FIGS. 2 and 3, the reflective portion 130 may include a flat surface 131 disposed at a central portion of the second area A2 and an inclined surface 132 connected to the flat surface 131. The flat surface 131 may be disposed in parallel with the bottom surface 120b (shown in FIG. 2) of the pattern portion 120. The inclined surface 132 may be formed to be inclined along the profile of the inclined surface 120s of the pattern portion 120. Most of the light, which is directed toward the subpixel SP adjacent thereto among the light emitted from the subpixel SP for emitting light, may be reflected by the inclined surface 132 of the reflective portion 130 and then emitted to the light emission area EA of the subpixel SP for emitting light or the non-light emission area NEA of the subpixel SP for emitting light.

In the display apparatus 100 according to one embodiment of the present disclosure, the distance between the light emission area EA and the reflective portion 130 disposed to be inclined with respect to the non-light emission area NEA may be optimized to increase the amount of the light reaching the reflective portion 130 while minimizing the light trapped in the concave portion 141, whereby overall light efficiency (or light extraction efficiency) may be improved. An optimal distance between the light emission area EA and the reflective portion 130 may be derived by an equation related to an aspect ratio constant of the concave portion 141, an effective refractive index of the light emitting layer 116, a width and depth of the reflective portion 130.

For example, a horizontal distance H from the end of the light emission area EA of each of the plurality of subpixels SP to the reflective portion 130 may be provided to satisfy

$$H = {ae}^{\frac{b}{{n}_{h}}} \times V - S .$$

In the above equation, ‘a’ is an aspect ratio constant of the concave portion 141 included in the light extraction portion 140, ‘e’ is a natural log, ‘b’ is an effective refractive index of the light emitting layer 116, ‘nₕ’ is a refractive index of the second layer 1132, ‘V’ is a vertical distance from a lower surface of the reflective portion 130 on an upper surface of the light emitting layer 116, which is in contact with the bottom surface 120b of the pattern portion, to a highest point of the reflective portion 130 in the non-light emission area NEA, and ‘S’ may be a horizontal distance from a crossing point, at which a horizontal extension line on the upper surface of the light emitting layer 116 in the light emission area EA crosses the reflective portion 130, to an inflection point at which the reflective portion 130 is inflected in the second area A2.

The vertical distance may be a direction parallel with the third direction (Z-axis direction). The horizontal distance may be a direction parallel with the first direction (X-axis direction).

‘V’ may be expressed as a distance from the lower surface of the reflective portion 130 at the highest point in the non-light emission area NEA to the lower surface of the reflective portion 130 at the inflection point where the reflective portion 130 is inflected.

‘H’ may mean the horizontal distance (or the shortest distance) from the end of the light emission area EA of each of the plurality of subpixels SP to the reflective portion 130. In this case, the horizontal distance may refer to a direction parallel with the first direction (X-axis direction) or a direction parallel with the upper surface of the substrate 110. The reference of ‘H’ in the third direction (Z-axis direction) may be the lower surface of the reflective electrode 117 in the light emission area EA. As shown in FIG. 3, the horizontal distance H (or the shortest distance) from the end of the light emission area EA to the reflective portion 130 may be formed in the first area A1.

The aspect ratio constant ‘a’ of the concave portion 141 is a constant derived through an aspect ratio efficiency conversion experiment by the inventor of the display apparatus, which is reflected by the reflective portion 130 in accordance with an aspect ratio of the concave portion 141. The aspect ratio of the concave portion 141 may mean flatness of the concave portion 141. For example, when the aspect ratio of the concave portion 141 is 0.0, the concave portion 141 may be formed to be flat, and the aspect ratio constant ‘a’ may have a value of about 0.15. When the aspect ratio of the concave portion 141 is 0.5, the concave portion 141 may be provided in a hemispherical shape having a depth smaller than a radius and the aspect ratio constant ‘a’ may have a value of about 0.08. When the aspect ratio of the concave portion 141 is 1.0, the concave portion 141 may be provided in a hemispherical shape having a predetermined radius and the aspect ratio constant ‘a’ may have a value of about 0.05. When the aspect ratio of the concave portion 141 is 1.5, the concave portion 141 may be provided in a hemispherical shape having a depth greater than a radius and the aspect ratio constant ‘a’ may have a value of about 0.02. Therefore, in the display apparatus 100 according to one embodiment of the present disclosure, the concave portion 141 may have an aspect ratio constant ‘a’ of 0.02 to 0.15.

The effective refractive index ‘b’ of the light emitting layer 116 may mean a refractive index calculated by a wave equation when the entire light emitting layer 116 emits light, instead of a refractive index of each of a plurality of stacked layers included in the light emitting layer 116, for example, a refractive index of each of a hole injection layer, a hole transporting layer, an organic light emitting layer, an electron injection layer and an electron transporting layer. The wave equation may be an equation related to a thickness and a refractive index of each of the plurality of layers included in the light emitting layer 116 and a position component in a vertical direction in which an exciton is formed.

Meanwhile, as shown in FIG. 3, since the reflective portion 130 is formed along the profile of the pattern portion 120, the reflective portion 130 may be inflected on the bottom surface 120b of the pattern portion 120. That is, the reflective portion 130 may be inflected from the inclined surface 132 to the flat surface 131 on the bottom surface 120b of the pattern portion 120. In this case, inflection may include switching of the inclined surface to the flat surface. Therefore, the inflection point at which the reflective portion 130 is inflected may mean a point at which the inclined surface 132 of the reflective portion 130 is switched to the flat surface 131.

‘V’ refers to a depth of the reflective portion 130 in the non-light emission area NEA, and the depth may be a vertical distance from the lower surface of the reflective portion 130 at the highest point in the non-light emission area NEA to the lower surface of the reflective portion 130 at the inflection point at which the reflective portion 130 is inflected. In this case, the vertical distance may refer to a direction parallel with the third direction (Z-axis direction) or a direction perpendicular to the upper surface of the substrate 110. As shown in FIG. 2, the lower surface of the reflective portion 130 at the highest point in the non-light emission area NEA may be the upper surface (or point) of the light emitting layer 116 on the bank 115 most protruded toward the opposing substrate 200 from the bank 115 in the first area A1. The shortest distance from a virtual line horizontally extended from the point to the lower surface of the reflective portion 130 at the inflection point at which the reflective portion 130 is inflected may be the depth V of the reflective portion 130.

‘S’ indicates a width of a portion of the reflective portion 130 in the non-light emission area NEA, and the width may be a horizontal distance from a crossing point, at which the end of the light emission area EA crosses the reflective portion 130, to the inflection point at which the reflective portion 130 is inflected. As shown in FIG. 3, the crossing point at which the end of the light emission area EA crosses the reflective portion 130 may be an end point of the horizontal distance ‘H’. A horizontal distance from the end point of the horizontal distance ‘H’ to the inflection point at which the reflective portion 130 is inflected may be the width ‘S’ of a portion of the reflective portion 130. In another expression, the width ‘S’ of a portion of the reflective portion 130 may be the width ‘S’ of a portion of the reflective portion 130 disposed to be inclined in the first area A1. As shown in FIG. 3, the reflective portion 130 in the first area A1 may be inclined to form a predetermined angle θ from a horizontal extension line of the lower surface of the reflective electrode 117 in the light emission area EA. For example, the predetermined angle θ may be an acute angle.

In the display apparatus 100 according to one embodiment of the present disclosure, the reflective portion 130 may be disposed in the non-light emission area NEA to satisfy the above equation, so that light, which is directed toward an adjacent subpixel, may be reflected toward the substrate 110 by the reflective portion 130, whereby light extraction efficiency may be improved.

As described above, when the reflective portion 130 is disposed to be too close to the light emission area EA, light reflectance by the wave guide is improved, but the light is trapped by the concave portion 141 of the light extraction portion 140, whereby light extraction efficiency may be deteriorated. On the contrary, when the reflective portion 130 is disposed to be far away from the light emission area EA, the amount of light reaching the reflective portion 130 is reduced, whereby light extraction efficiency may be deteriorated. However, in the display apparatus 100 according to one embodiment of the present disclosure, the distance between the light emission area EA and the reflective portion 130 disposed to be inclined with respect to the non-light emission area NEA may be provided as an optimal distance, which satisfies the above equation, to increase the amount of the light reaching the reflective portion 130 while minimizing the light trapped in the concave portion 141, whereby overall light efficiency (or light extraction efficiency) may be improved.

Meanwhile, the display apparatus 100 according to one embodiment of the present disclosure may be provided in a bank-less structure in which the bank 115 shown in FIG. 3 is omitted. In this case, since the bank 115 is omitted, the depth ‘V’ of the reflective portion 130 in the non-light emission area NEA may be reduced, and the width ‘S’ of a portion of the reflective portion 130 may be also reduced. In case of the bank-less structure, since the end of the light emission area EA is widened to the end of the pixel electrode 114, the horizontal distance ‘H’ between the end of the light emission area EA and the reflective portion 130 may be reduced. Therefore, when the display apparatus 100 according to one embodiment of the present disclosure is provided in the bank-less structure in FIG. 3, the width of the light emission area EA is widened as compared with the case that the bank is provided in the display apparatus 100, whereby light emission efficiency may be further improved.

Referring to FIG. 2, the plurality of grooves PG overlaps with both the reflective electrode 117 and the pixel electrode 114 from a plan view. The example embodiment of FIG. 2 shows four grooves PG. However, the number of grooves PG may vary according to different embodiments. The plurality of grooves PG has an entire width of W2 in the X-axis direction.

The pixel electrode has a width W1 in the same X-axis direction as shown in FIG. 2. The width W1 of the pixel electrode may be defined between the distance between a first end point P1 of the pixel electrode and a second end point P2 of the pixel electrode. Here, width W1 of the pixel electrode is greater than width W2 of the plurality of grooves PG in the X-axis direction.

Similarly, the second overcoat layer 1132 includes a first end point C1 and a second end point C2 opposite the first end point C1. The second overcoat layer 1132 has a width W3 defined between the first end point C1 and the second end point C2. In one embodiment, width W3 of the second overcoat layer 1132 is greater than width W1 of the pixel electrode and width W2 of the plurality of grooves PG.

According to FIG. 2, the bank layer 115 extends towards the substrate 110 and contacts the first overcoat layer 1131. That is, the bank layer 115 extends downwards along the inclined surface of the second overcoat layer 1132. The bank layer 115 contacts the first overcoat layer 1131 at a location adjacent to the first end point C1 (or the second end point C2). Here, a surface of the bank layer 115 that contacts the first overcoat layer 1131 and a surface of the second overcoat layer 1132 that contacts the first overcoat layer 1131 are coplanar with each other.

Similarly, a surface of the bank layer 115 that contacts the first overcoat layer 1131, a surface of the second overcoat layer 1132 that contacts the first overcoat layer 1131, a surface of the light emitting layer 116 that contacts the first overcoat layer 1131 are coplanar with each other (see the coplanar surface adjacent to first end point C1 or the second end point C2 in FIG. 2).

In some embodiments, the light emitting layer 116 continuously and contiguously extends from the light emitting element E and contacts the first overcoat layer 1131 (see area A2 in FIG. 2). The light emitting layer 116 contacts the first overcoat layer at a location adjacent to the plurality of grooves PG as shown in FIG. 2.

Referring to FIG. 3, the bank layer 115 includes a bump portion BP adjacent to one end P2 of the pixel electrode 114. As shown, the bump portion BP has a round surface that protrudes in an opposite direction of the substrate 110. Here, the light emitting layer 116 continuously and contiguously extends from the light emitting element E and extends over the bump portion BP of the bank layer 115.

The bank layer 115 has a first end point B1 and a second end point B2 opposite the first end point B1. The first area A1 of the first subpixel SP1 may also be defined as an area between the first end point B1 and the second end point B2. Similarly, the bank layer 115 has a third end point B3 and a fourth end point B4 opposite the third end point B3. The first area A1 of the second subpixel SP2 may also be defined as an area between the third end point B3 and the fourth end point B4. The second area A2 between the first and second subpixels SP1, SP2 may be defined as an area between the second end point B2 and the third end point B3.

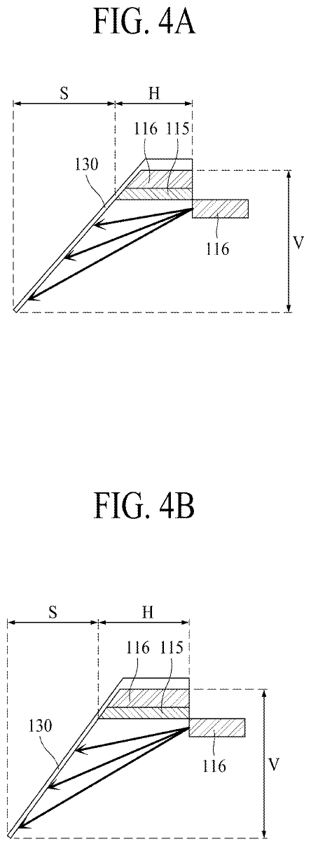

Hereinafter, the case that the horizontal distance H from the light emission area EA to the reflective portion 130 disposed to be inclined with respect to the non-light emission area NEA is formed as the optimal distance that satisfies the above equation will be described in more detail with reference to FIGS. 4A to 5.

FIGS. 4A and 4B are various examples schematically illustrating a portion of a display apparatus according to one embodiment of the present disclosure, FIG. 4C illustrates a comparative example, and FIG. 5 is a schematic graph illustrating light efficiency based on a distance between a light emission area and a reflective portion of FIGS. 4A to 4C.

Referring to FIGS. 4A and 4B, in the display apparatus 100 according to one embodiment of the present disclosure, the depth V of the reflective portion 130 disposed in the non-light emission area NEA may be greater than the horizontal distance H from the end of the light emission area EA to the reflective portion 130. When the depth V of the reflective portion 130 disposed in the non-light emission area NEA is greater than the horizontal distance H, a reflection area for reflecting light may be greater than the case that the depth of the reflective portion is equal to or smaller than the horizontal distance. Therefore, the display apparatus 100 according to one embodiment of the present disclosure may improve light extraction efficiency through the reflective portion 130 of the non-light emission area NEA, thereby improving overall light efficiency.

For example, in case of the display apparatus having no reflective portion, assuming that efficiency of light emitted from the light emitting layer and emitted vertically is 100%, light loss due to a wave guide generated by the interface between the light emitting element layer and the electrode may be about 40%. In the display apparatus 100 according to one embodiment of the present disclosure, the reflective portion 130 may be disposed at a position spaced apart from the light emission area EA to reflect light, which is directed toward the subpixel SP adjacent thereto, to the subpixel for emitting light through the wave guide. Therefore, in the display apparatus 100 according to one embodiment of the present disclosure, light of about 40% lost by the wave guide may be emitted to the substrate 110 through the reflective portion 130, whereby overall light efficiency (or light extraction efficiency) may be improved.

Referring back to FIGS. 4A and 4B, in the display apparatus 100 according to one embodiment of the present disclosure, ‘S’ may be smaller than ‘V’ and greater or smaller than ‘H’. That is, the horizontal distance S from the crossing point, at which the end of the light emission area EA crosses the reflective portion 130, to the inflection point, at which the reflective portion 130 is inflected, may be smaller than the depth V of the reflective portion 130 disposed in the non-light emission area NEA and may be greater or smaller than the horizontal distance H (or the shortest distance) from the end of the light emission area EA of each of the plurality of subpixels SP to the reflective portion 130. This may be expressed by the equation of V>S≥ H.

FIG. 4A is a schematic view illustrating V>S>H. That is, FIG. 4A illustrates that the horizontal distance S from the crossing point at which the end of the light emission area EA crosses the reflective portion 130 to the inflection point at which the reflective portion 130 is inflected is smaller than the depth V of the reflective portion 130 disposed in the non-light emission area NEA and is greater than the horizontal distance H (or the shortest distance) from the end of the light emission area EA of each of the plurality of subpixels SP to the reflective portion 130. In this case, when ‘S’ is defined as a first length, ‘V’ is defined as a second length and ‘H’ is defined as a third length, as shown in FIG. 4A, the second length is longer than each of the first length and the third length, so that most of the light emitted from the light emission area EA and directed toward the adjacent subpixel SP may be reflected by the reflective portion 130. Therefore, the display apparatus 100 according to one embodiment of the present disclosure may improve light extraction efficiency through the reflective portion 130.

FIG. 4B is a schematic view illustrating V>S=H. That is, FIG. 4B illustrates that the horizontal distance S from the crossing point at which the end of the light emission area EA crosses the reflective portion 130 to the inflection point at which the reflective portion 130 is inflected is smaller than the depth V of the reflective portion 130 disposed in the non-light emission area NEA and is equal to the horizontal distance H (or the shortest distance) from the end of the light emission area EA of each of the plurality of subpixels SP to the reflective portion 130. In this case, when ‘S’ is defined as a first length, ‘V’ is defined as a second length and ‘H’ is defined as a third length, as shown in FIG. 4B, the second length is longer than the first length and the first length is equal to the third length, so that most of the light emitted from the light emission area EA and directed toward the adjacent subpixel SP may be reflected by the reflective portion 130. Therefore, the display apparatus 100 according to one embodiment of the present disclosure may improve light extraction efficiency through the reflective portion 130.

On the contrary, FIG. 4C illustrates a comparative example in which a width and depth of the reflective portion and a distance between the light emission area and the reflective portion do not satisfy V>S≥ H.

For example, FIG. 4C illustrates V<S or V<H.

As shown in FIG. 4C, when the second length V is smaller less than the first length S or smaller than the third length H, most of the light emitted from the light emission area EA and directed toward the adjacent subpixel SP may not be reflected by the reflective portion 130. That is, since the reflective portion 130 disposed in the non-light emission area NEA is disposed to be far away from the light emission area EA and has a low depth, most of the light directed toward the adjacent subpixel SP may not be reflected by the reflective portion 130. Since the light that is not reflected by the reflective portion 130 may be emitted toward the adjacent subpixel SP, occurrence of color mixture between the subpixels SP may be increased in the comparative example shown in FIG. 4C.

In the display apparatus 100 according to one embodiment of the present disclosure, ‘S’ is smaller than ‘V’ and is greater or smaller than H so that most of the light emitted from the light emission area EA and directed toward the adjacent subpixel SP may be reflected by the reflective portion 130, whereby color mixture may be avoided and overall light efficiency (or light extraction efficiency) may be improved.

FIG. 5 is a graph illustrating that light efficiency based on the horizontal distance H (or the shortest distance) (or the third length H) from the end of the light emission area EA to the reflective portion 130 in each of FIGS. 4A, 4B and 4C.

Referring to FIG. 5, X-axis represents the third length H, for example, 1 micrometer (μm) to 12 micrometer (μm). Y-axis represents a normalization power of a comparative value with respect to a target value. The comparative value corresponds to the case that the light emitted from the light emission area EA and directed toward the adjacent subpixel SP is not partially reflected by the reflective portion 130 when the third length H is greater than the first length S and smaller than the second length V. The target value corresponds to the case of FIGS. 4A, 4B and 4C. LN1, LN2 and LN3 are graphs of the display apparatus according to FIGS. 4A to 4C in which the reflective portion 130 is provided at the position spaced apart from the light emission area EA. As described above, FIGS. 4A and 4B illustrate a schematic cross-sectional structure of the display apparatus according to one embodiment of the present disclosure, which satisfies V>S>H, and FIG. 4C illustrates a schematic cross-sectional structure of the display apparatus, which does not satisfy V>S≥ H.

As shown in FIG. 5, it can be seen that when H is between about 3 micrometers and about 6 micrometers, light efficiency of LN1 is greater than or equal to that of LN2 and LN3 as much as 0 or more. It can be seen that when H is between about 3 micrometers and about 5 micrometers, light efficiency of LN2 is greater than 0 and smaller than that of LN1. It can be seen that when His between about 1 micrometer and about 12 micrometers, light efficiency of LN3 is smaller than that of LN1 and LN2.

Consequently, in the display apparatus 100 according to one embodiment of the present disclosure, H is 3 micrometers (μm) to 6 micrometers (μm) and satisfies V>S≥ H, so that color mixture between the subpixels SP may be avoided and overall light efficiency (or light extraction efficiency) may be improved.

According to the present disclosure, the following advantageous effects may be obtained.

In the display apparatus according to the present disclosure, as the reflective portion is provided to be spaced apart from the light emission area at an optimal distance in the non-light emission area, light extraction may be performed even in the non-light emission area, whereby overall light efficiency may be improved.

In the display apparatus according to the present disclosure, since light may be extracted even from the non-light emission area, the display apparatus according to the present disclosure may have the same light emission efficiency or more improved light emission efficiency even with low power as compared with the display apparatus having no reflective portion, whereby overall power consumption may be reduced.

In the display apparatus according to the present disclosure, each of the plurality of subpixels includes the light extraction portion that includes the plurality of concave portions, so that light extraction efficiency of the light emitted from the light emitting element layer may be maximized.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is intended to cover all variations or modifications derived from the meaning, scope and equivalent concept described within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display apparatus comprising:
a substrate having a plurality of pixels having a plurality of subpixels;
a pattern portion disposed on the substrate and formed to be concave between the plurality of subpixels; and
a reflective portion on the pattern portion,
wherein the plurality of subpixels includes a light emission area and a non-light emission area adjacent to the light emission area, and a light extraction portion that overlaps the light emission area and includes a plurality of concave portions, and
wherein the reflective portion is adjacent to the light extraction portion in the non-light emission area and is disposed to be spaced apart from the light emission area.

2. The display apparatus of claim 1, wherein the non-light emission area includes a first area adjacent to the light emission area and a second area adjacent to the first area and spaced apart from the light emission area,
wherein the light extraction portion is disposed to be adjacent to the pattern portion, and
wherein the pattern portion includes an inclined surface formed in the first area and a bottom surface extended from the inclined surface and formed up to the second area.

3. The display apparatus of claim 2, wherein the plurality of subpixels further includes an overcoat layer on the substrate and a pixel electrode on the overcoat layer,
wherein the overcoat layer includes:
a first layer including the plurality of concave portions; and
a second layer between the first layer and the pixel electrode, and
wherein the second layer is extended to the first area and is in contact with a portion of the bottom surface of the pattern portion while covering the inclined surface of the pattern portion.

4. The display apparatus of claim 2, wherein the plurality of subpixels further includes a first layer on the substrate, a second layer on the first layer, and a light emitting layer on the second layer,
wherein a horizontal distance ‘H’ from an end of the light emission area of each of the plurality of subpixels to the reflective portion satisfies
$$H = {ae}^{\frac{b}{{n}_{h}}} \times V - S ,$$
where ‘a’ is an aspect ratio constant of the concave portion, ‘e’ is a natural log, ‘b’ is an effective refractive index of the light emitting layer, ‘nₕ’ is a refractive index of the second layer, ‘V’ is a vertical distance from a lower surface of the reflective portion on an upper surface of the light emitting layer, which is in contact with the bottom surface of the pattern portion, to a highest point of the reflective portion in the non-light emission area, and ‘S’ is a horizontal distance from a crossing point, at which a horizontal extension line of the upper surface of the light emitting layer in the light emission area crosses the reflective portion, to an inflection point at which the reflective portion is inflected in the second area.

5. The display apparatus of claim 1, wherein ‘S’ is smaller than ‘V’ and greater or smaller than ‘H’.

6. The display apparatus of claim 1, further comprising a light emitting element layer in the plurality of subpixels,
wherein the light emitting element layer includes:
a pixel electrode in the light emission area;
a light emitting layer on the pixel electrode and the non-light emission area; and
a reflective electrode on the light emitting layer, and
wherein the reflective portion is a portion of the reflection electrode.

7. The display apparatus of claim 1, wherein the pattern portion surrounds the light emission area.

8. The display apparatus of claim 3, wherein the pattern portion is formed to be concave on the first layer.

9. The display apparatus of claim 1, wherein the pattern portion is disposed to be spaced apart from the light emission area.

10. The display apparatus of claim 1, wherein a width of the pattern portion is reduced in a direction that is directed toward the substrate from the reflective portion.

11. The display apparatus of claim 2, wherein the bottom surface of the pattern portion is disposed to be closer to the substrate than the pixel electrode in the light emission area.

12. The display apparatus of claim 2, wherein the inclined surface of the pattern portion forms an obtuse angle with respect to the bottom surface.

13. The display apparatus of claim 11, further comprising a bank covering an edge of the pixel electrode,
wherein the bank is disconnected on the bottom surface of the pattern portion.

14. The display apparatus of claim 3, wherein a refractive index of the second layer is greater than that of the first layer.

15. The display apparatus of claim 3, wherein an upper surface of the second layer is provided to be flat.

16. The display apparatus of claim 3, further comprising a bank covering an edge of the pixel electrode,
wherein the bank is extended to cover an inclined surface of the second layer covering an inclined surface of the pattern portion and is in contact with a portion of the bottom surface of the pattern portion.

17. The display apparatus of claim 16, wherein each of the second layer and the bank on the bottom surface of the pattern portion is discontinuous.

18. A display apparatus comprising:
a substrate having a plurality of pixels having a plurality of subpixels;
a pattern portion disposed on the substrate and formed to be concave between the plurality of subpixels; and
a reflective portion on the pattern portion,
wherein the plurality of subpixels includes a light emission area and a non-light emission area adjacent to the light emission area, and
wherein a depth of the reflective portion disposed in the non-light emission area is greater than a horizontal distance from an end of the light emission area to the reflective portion.

19. The display apparatus of claim 18, wherein the plurality of subpixels further includes a light emitting layer that is provided in the light emission area and the non-light emission area below the reflective portion,
wherein the pattern portion includes an inclined surface formed in a first area of the non-light emission area adjacent to the light emission area and a bottom surface extended from the inclined surface and formed up to a second area adjacent to the first area, and
wherein a depth of the reflective portion disposed in the non-light emission area is a vertical distance from a lower surface of the reflective portion on an upper surface of the light emitting layer, which is in contact with the bottom surface of the pattern portion, to a highest point of the reflective portion in the non-light emission area.

20. The display apparatus of claim 18, further comprising a light emitting element layer in the plurality of subpixels,
wherein the light emitting element layer includes:
a pixel electrode in the light emission area;
a light emitting layer on the pixel electrode and the non-light emission area; and
a reflective electrode on the light emitting layer, and
wherein the reflective portion is a portion of the reflection electrode.

21. The display apparatus of claim 19, wherein the plurality of subpixels further includes a first layer on the substrate, including a light extraction portion having a plurality of concave portions, a second layer on the first layer, and a light emitting layer on the second layer,
a horizontal distance ‘H’ from an end of the light emission area of each of the plurality of subpixels to the reflective portion satisfies
$$H = {ae}^{\frac{b}{{n}_{h}}} \times V - S ,$$
where ‘a’ is an aspect ratio constant of the concave portion, ‘e’ is a natural log, ‘b’ is an effective refractive index of the light emitting layer, ‘nₕ’ is a refractive index of the second layer, ‘V’ is a depth of the reflective portion, and ‘S’ is a horizontal distance from a crossing point, at which a horizontal extension line of the upper surface of the light emitting layer in the light emission area crosses the reflective portion, to an inflection point at which the reflective portion is inflected in the second area.

22. The display apparatus of claim 21, wherein ‘S’ is smaller than ‘V’ and greater or smaller than ‘H’.

23. The display apparatus of claim 21, wherein the second area is spaced apart from the light emission area, and
wherein the light extraction portion is disposed to be adjacent to the pattern portion.

24. The display apparatus of claim 23, wherein the plurality of subpixels further includes a pixel electrode between the second layer and the light emitting layer, and
wherein the second layer is extended to the first area and is in contact with a portion of the bottom surface of the pattern portion while covering the inclined surface of the pattern portion.

25. A display apparatus comprising:
a substrate having a plurality of pixels, each pixels of the plurality including a plurality of subpixels;
a first overcoat layer on the substrate, the first overcoat layer having a first surface;
a plurality of grooves at the first surface of the first overcoat layer;
a light emitting element including a pixel electrode, a reflective electrode, and a light emitting layer between the pixel electrode and the reflective electrode, the light emitting element on the plurality of grooves,
wherein the plurality of grooves overlaps with both the reflective electrode and the pixel electrode from a plan view,
wherein the pixel electrode has a first width in a first direction, and
wherein the first width of the pixel electrode is greater than a second width of the plurality of grooves in the first direction.

26. The display apparatus of claim 25, comprising a second overcoat layer on the first overcoat layer,
wherein the second overcoat layer includes a first end and a second end opposite the first end, the second overcoat layer has a third width in the first direction between the first end and the second end,
wherein the third width of the second overcoat layer is greater than the first width of the pixel electrode.

27. The display apparatus of claim 26, comprising a bank layer on the second overcoat layer and the pixel electrode,
wherein the bank layer is disposed along an inclined surface of the second overcoat layer, and
wherein the inclined surface of the second overcoat layer is adjacent to the plurality of grooves.

28. The display apparatus of claim 27, wherein the bank layer extends towards the substrate and contacts the first overcoat layer.

29. The display apparatus of claim 27, wherein a surface of the bank layer that contacts the first overcoat layer and a surface of the second overcoat layer that contacts the first overcoat layer are coplanar with each other.

30. The display apparatus of claim 25, wherein the light emitting layer continuously and contiguously extends from the light emitting element and contacts the first overcoat layer.

31. The display apparatus of claim 30, wherein the light emitting layer contacts the first overcoat layer at a location adjacent to the plurality of grooves.

32. The display apparatus of claim 31, wherein a surface of the bank layer that contacts the first overcoat layer, a surface of the second overcoat layer that contacts the first overcoat layer, a surface of the light emitting layer that contacts the first overcoat layer are coplanar with each other.

33. The display apparatus of claim 27, wherein the bank layer includes a bump portion adjacent to one end of the pixel electrode,
wherein the bump portion has a round surface that protrudes in an opposite direction of the substrate, and
wherein the light emitting layer continuously and contiguously extends from the light emitting element and extends over the bump portion of the bank layer.
